(19) United States
(12) Patent Application Publication
(10) Pub. No.: US 2002/0167376 A1
(43) Pub. Date: Nov. 14, 2002

(54) Piezoelectric filter

(75) Inventor: Masao Gamo, Takaoka-shi (JP)

Correspondence Address: Keating & Bennett LLP, 10400 Eaton Place, Suite 312, Fairfax, VA, 22030, US

(73) Assignee: Murata Manufacturing Co., Ltd., Nagaokakyo-shi (JP)

(21) Appl. No.: 10/127,476

(22) Filed: Apr. 23, 2002

(30) Foreign Application Priority Data
May 11, 2001 (JP) 2001-142037

(51) Int. Cl. H03H 9/00

(52) U.S. Cl. 333/187

(57) ABSTRACT

A piezoelectric filter includes a first three-terminal filter having a first input part and a first output part, a second three-terminal filter which has a second input part connected to the first output part and a second output part, a ground part, a relay capacitance connected between the first output part, the second input part, and the ground part, and an additional capacitance connected between the first or second input part and the first or second output part.

### BACKGROUND OF THE INVENTION

1. Field of the Invention

The present invention relates to a piezoelectric filter and more particularly, the present invention relates to a piezoelectric filter including two three-terminal filters connected in a cascade arrangement via a relay capacitance.

2. Description of the Related Art

Piezoelectric filters including two three-terminal filters connected in a cascade arrangement via a relay capacitance are used as filters of an intermediate-frequency stage for mobile communication devices such as mobile phones.

FIG. 1 shows one exemplary circuit configuration of such a piezoelectric filter. The piezoelectric filter includes a first three-terminal filter 1 having an output part 1a connected to an input part 2a of a second three-terminal filter 2. A relay capacitance 3 is connected between the output part 1a and a ground part 1b , and a ground part 2b and the input part 2a.

The requisite characteristics of such a piezoelectric filter include attenuation and selectivity. The selectivity of the piezoelectric filter shown in FIG. 1 is not suitable, as shown by the waveform A in FIG. 2. In this case, the center frequency of the pass band is set to 10.7 MHz. For improving the selectivity, a capacitance Ci, shown in broken lines, is connected between an input part and the output part 1a of the first three-terminal filter 1, and a capacitance Co, shown in broken lines, is connected between the input part 2a and an output part of the second three-terminal filter 2, as shown in FIG. 1.

Subsequently, the selectivity of the piezoelectric filter improves, as shown by the solid line B and the chain line C in FIG. 2. However, the attenuation around the pass band deteriorates. The solid line B shows the attenuation when the capacitances of the piezoelectric filter are defined by the equation:

Ci=Co=5 pF.

The chain line C shows the attenuation when the capacitances of the piezoelectric filter are defined by the equation:

Ci=Co=10 pF.

### SUMMARY OF THE INVENTION

In order to overcome the problems described above, preferred embodiments of the present invention provide a piezoelectric filter having greatly improved selectivity without experiencing any deterioration of the attenuation around the pass band.

According to a first preferred embodiment of the present invention, a piezoelectric filter includes a first three-terminal filter having a first input part and a first output part, a second three-terminal filter which has a second input part connected to the first output part, and a second output part, and a ground part. A relay capacitance is connected to the first output part, the second input part, and the ground part, and an additional capacitance Ca is connected between the first input part and the first output part, or between the second input part and the second output part.

The two three-terminal filters F1 and F2 are connected in a cascade arrangement via the relay capacitance Cr. The additional capacitance Co can be connected between the input part and the output part of either the three-terminal filter F1 or the three-terminal filter F2. In this case, however, the additional capacitance Co is connected between the input part and the output part of the three-terminal filter F2. Further, the additional capacitance Ci is not connected between the input part and the output part of the other three-terminal filter that is F1 in this preferred embodiment.

FIG. 4 shows the waveform obtained when the capacitances of the piezoelectric filter are defined by the equations:

Ci=0 and

Co=10 pF.

FIG. 4 also shows the waveform obtained when the capacitances of the piezoelectric filter are defined by the equation:

Ci=Co=0.

The center frequency of the pass band is preferably about 10.7 MHz.

As shown in this drawing, the attenuation around the pass band is suitable, as in the case of the known piezoelectric filter having no additional capacitance, having a characteristic that is shown by the broken line A in FIG. 2. Further, the selectivity of the piezoelectric filter of preferred embodiments of the present invention is suitable, as in the case of the known piezoelectric filter which has the additional capacitance Ci between the input part and the output part of the first three-terminal filter, and which has the additional capacitance Co between the input part and the output part of the second three-terminal filter. The characteristics of the known piezoelectric filter in such a case are shown by the solid line B and by the chain line C in FIG. 2.

In FIG. 3, the additional capacitance Co is connected between the input part and the output part of the three-terminal filter F2. However, the same effect can be obtained when the additional capacitance Ci is connected between the input part and the output part of the three-terminal filter F1.

Preferably, a piezoelectric filter further includes an input terminal for inputting a signal and an output terminal for outputting a signal, wherein the value of the additional capacitance Ca is at most approximately 1.5 times the value of the capacitance Cb between the input terminal and the output terminal.

Preferably, the first three-terminal filter further includes a first piezoelectric substrate, a first split electrode on one main surface of the first piezoelectric substrate, and a first common electrode, which faces the first split electrode, on the other main surface of the first piezoelectric substrate, and the second three-terminal filter further includes a second piezoelectric substrate, a second split electrode on one main surface of the second piezoelectric substrate, and a second common electrode, which faces the second split electrode, on the other main surface of the second piezoelectric substrate. The first piezoelectric substrate and the second piezoelectric substrate may be laminated on and bonded to each other, and the additional capacitance may be disposed on either the first piezoelectric substrate or the second piezoelectric substrate and between terminal electrodes which are connected to the first split electrode or the second split electrode.

That is to say, when the piezoelectric filter includes the piezoelectric substrates that are laminated on each another, the additional capacitance can be provided on the piezoelectric substrate of either the first three-terminal filter or the second three-terminal filter. Accordingly, the obtained piezoelectric filter is compact.

Preferably, the first three-terminal filter further includes a first piezoelectric substrate, a first split electrode on one main surface of the first piezoelectric substrate and a first common electrode, which faces the first split electrode, on the other main surface of the first piezoelectric substrate, and the second three-terminal filter further includes a second piezoelectric substrate, a second split electrode on one main surface of the second piezoelectric substrate, and a second common electrode, which faces the second split electrode, on the other main surface of the second piezoelectric substrate. The first piezoelectric substrate and the second piezoelectric substrate may be laminated on and bonded to each other. A first casing substrate may be bonded to the outside of the first piezoelectric substrate, and may include a first input terminal electrode and a first relay terminal electrode, which are connected to the first split electrode, and a first ground terminal electrode, which is connected to the first common electrode. A second casing substrate may be bonded to the outside of the second piezoelectric substrate, and may include a first output terminal electrode and a second relay terminal electrode, which are connected to the second split electrode, and a second ground terminal electrode, which is connected to the second common electrode. The additional capacitance may be provided between the first input terminal electrode and the first relay terminal electrode, or between the first output terminal electrode and the second relay terminal electrode.

That is to say, the piezoelectric filter includes two three-terminal filters each having the casing substrate laminated and bonded to the outside thereof. The additional capacitance is disposed in either of the casing substrates. In preferred embodiments of the present invention, the additional capacitance is preferably provided in the package of the surface-mounting type piezoelectric filter. This type of piezoelectric filter can be manufactured more easily than in the case where the additional capacitance is provided on the three-terminal filter, and can suppress the generation of unwanted vibrations.

Preferably, the relay terminal electrode and the ground terminal electrode may be provided on the top surface and the bottom surface, respectively, of either the first casing substrate or the second casing substrate so as to face each other. The relay capacitance may be provided between the relay terminal electrode and the ground terminal electrode.

That is to say, the relay capacitance is provided in one of the casing substrates defining the package of the surface-mounting type piezoelectric filter. Accordingly, an arbitrary relay capacitance can be achieved.

Other features, elements, characteristics and advantages of the present invention will become more apparent from the following detailed description of preferred embodiments of the present invention with reference to the attached drawings.

### BRIEF DESCRIPTION OF THE DRAWINGS

FIG. 1 shows the circuit configuration of a known piezoelectric filter;

FIG. 2 shows the filtering characteristic of the known piezoelectric filter;

FIG. 3 shows the circuit configuration of a piezoelectric filter according to a preferred embodiment of the present invention;

FIG. 4 shows the comparison between the filtering characteristic of the piezoelectric filter of a preferred embodiment of the present invention and the filtering characteristic of the known piezoelectric filter;

FIG. 5A shows how the characteristic of the piezoelectric filter of a preferred embodiment of the present invention varies in accordance with changes in the additional capacitance;

FIG. 5B also shows how the characteristic of the piezoelectric filter of a preferred embodiment of the present invention varies in accordance with changes in the additional capacitance;

FIG. 5C also shows how the characteristic of the piezoelectric filter of a preferred embodiment of the present invention varies in accordance with changes in the additional capacitance;

FIG. 6 is a perspective view of an exemplary piezoelectric filter according to a preferred embodiment of the present invention;

FIG. 7 is a sectional view of the exemplary piezoelectric filter shown in FIG. 6 taken along the line X-X;

FIG. 8 is an exploded perspective view of the piezoelectric filter shown in FIG. 6;

FIG. 9 is a perspective view of a first three-terminal filter of the piezoelectric filter shown in FIG. 6;

FIG. 10 is a perspective view of a second three-terminal filter of the piezoelectric filter shown in FIG. 6;

FIG. 11A shows the top surface of a first casing substrate used in a preferred embodiment of the present invention;

FIG. 11B shows the bottom surface of the first casing substrate used in a preferred embodiment of the present invention;

FIG. 12A shows the top surface of a second casing substrate used in a preferred embodiment of the present invention;

FIG. 12B shows the bottom surface of the second casing substrate used in a preferred embodiment of the present invention; and

FIG. 13 is a perspective view of a second three-terminal filter according to another preferred embodiment of the present invention.

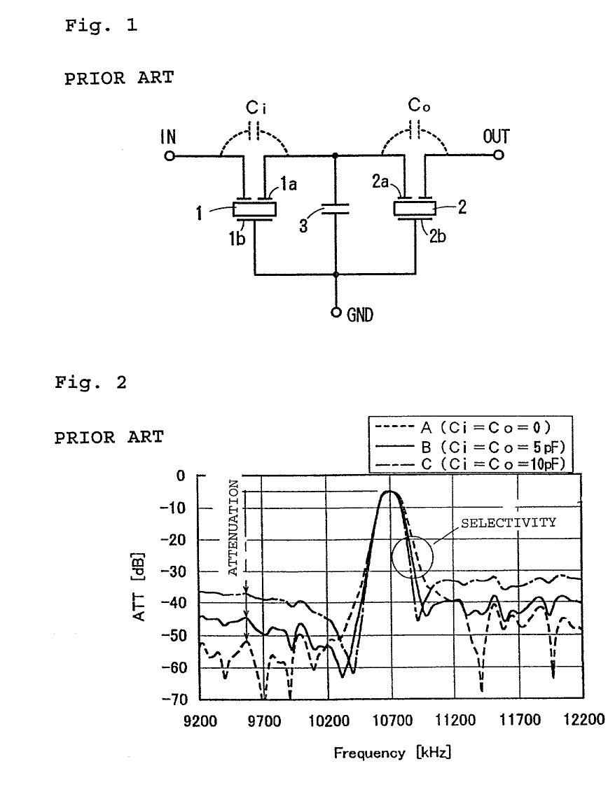

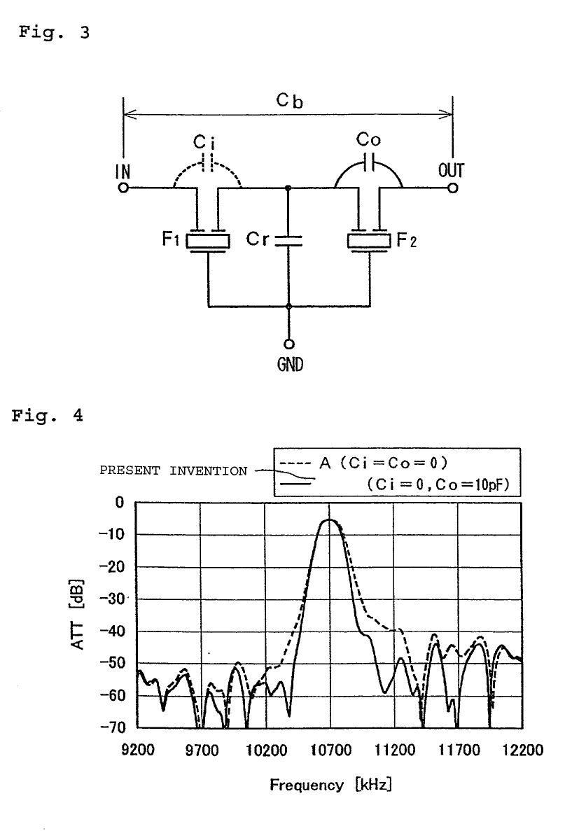

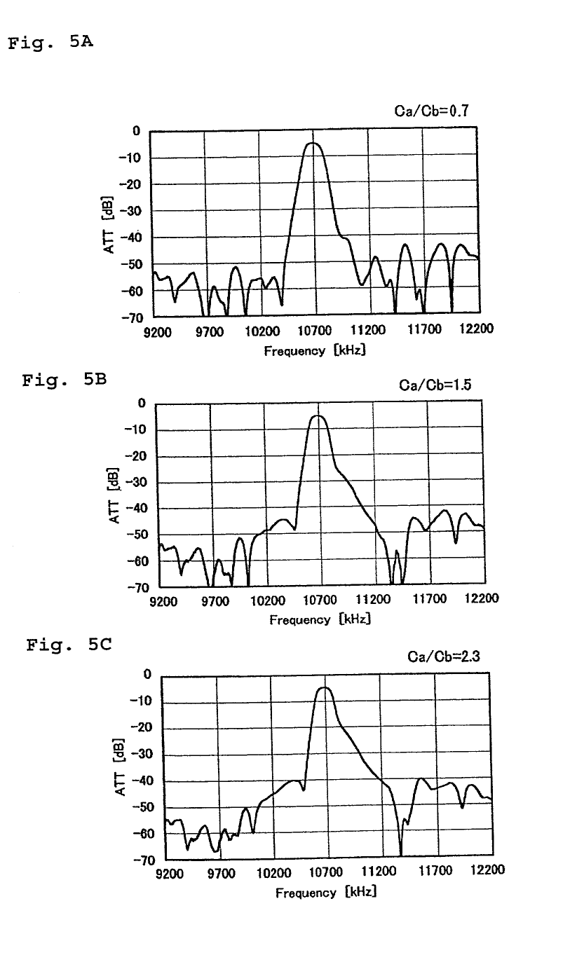

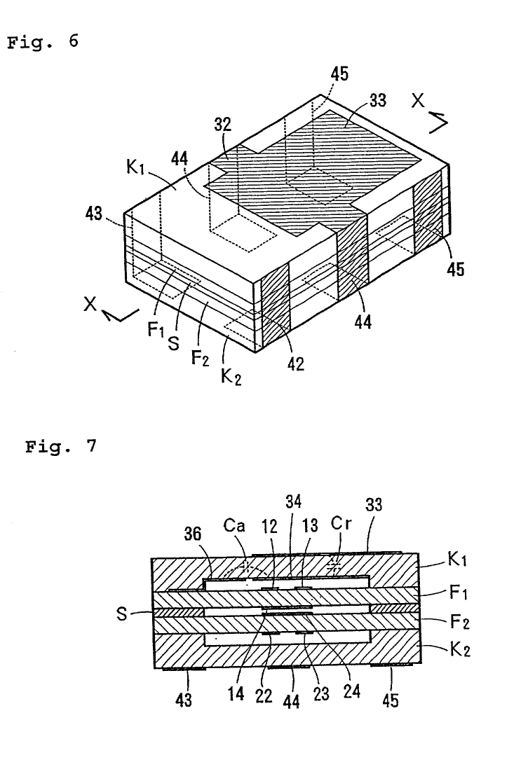

### DETAILED DESCRIPTION OF PREFERRED EMBODIMENTS

FIGS. 6, 7, 8, 9, and 10 show a piezoelectric filter according to a first preferred embodiment of the present invention. This piezoelectric filter is preferably a surface-mounting chip, and includes a substantially rectangular, sheet-like first three-terminal filter F1, a substantially rectangular, sheet-like second three-terminal filter F2, a frame-shaped adhesive layer S for bonding the first and second three-terminal filters F1 and F2, a first casing substrate K1 laminated on and bonded to the outside of the first three-terminal filter F1, and a second casing substrate K2 laminated on and bonded to the outside of the second three-terminal filter F2.

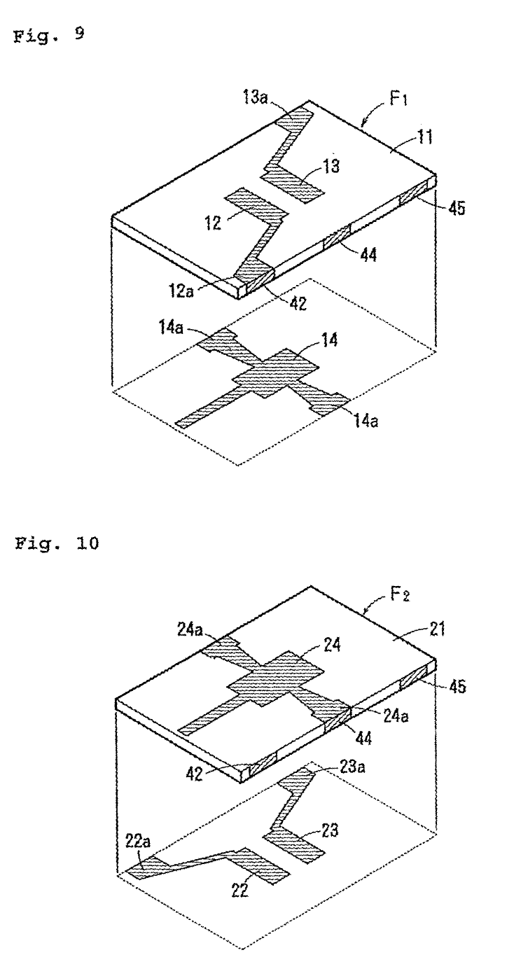

As shown in FIG. 9, the first three-terminal filter F1 includes a split electrode 12 and a split electrode 13 which are arranged with a predetermined distance therebetween on the top surface of a piezoelectric substrate 11 preferably made of a piezoelectric ceramic or a single piezoelectric crystal. The first three-terminal filter F1 further includes a common electrode 14 which is disposed on the bottom surface of the piezoelectric substrate 11 and which faces the split electrodes 12 and 13. These split electrodes 12 and 13 and the common electrode 14 define a dual-mode filter that traps energy by using thickness expander vibrations. In this drawing, the common electrode 14 provided on a bottom surface of the piezoelectric substrate 11 is shown as a projection chart. The split electrode 12 is connected to a terminal electrode 12a for inputting a signal which is disposed on one of the corners of the piezoelectric substrate 11. The split terminal 13 is connected to a terminal electrode 13a that is provided for relaying and is provided on the other corner of the piezoelectric substrate 11 diagonally opposite to the corner on which the terminal electrode 12a is provided. The common electrode 14 is connected to two terminal electrodes 14a that are provided for grounding and are disposed at the approximate center of the longitudinal sides of the piezoelectric substrate 11.

As shown in FIG. 10, the second three-terminal filter F2 includes split electrodes 22 and 23 that are arranged with a predetermined distance therebetween on the bottom surface of a piezoelectric substrate 21, which is preferably made of a piezoelectric ceramic or a single piezoelectric crystal. The second three-terminal filter F2 further includes a common electrode 24 which is disposed on the top surface of the piezoelectric substrate 21 and which faces the split electrodes 22 and 23. As in the case of the first three-terminal filter F1, the split electrodes 22 and 23 and the common electrode 24 define a dual-mode filter which traps energy by using a thickness expander vibration. In this drawing, the split electrodes 22 and 23 provided on a bottom surface of the piezoelectric substrate 21 are shown as a projection chart. The split electrode 22 is connected to a terminal electrode 22a for outputting the signal which is disposed on one of the corners of the piezoelectric substrate 21, and the split terminal 23 is connected to a terminal electrode 23a , that is provided for relaying and is disposed on the other corner of the piezoelectric substrate 21. The terminal electrode 23a and the terminal electrode 13a are disposed at corresponding positions along the thickness direction. The common electrode 24 is connected to two terminal electrodes 24a that are provided for grounding and are disposed at the approximate center of the longitudinal sides of the piezoelectric substrate 21. The terminal electrodes 24a for grounding and the terminal electrodes 14a are disposed at corresponding positions along the thickness direction of the piezoelectric filter.

The first three-terminal filter F1 and the second three-terminal F2 are laminated and bonded via the frame-shaped adhesive layer S. Since the adhesive layer S has an opening S1, a vibration space is defined between the three-terminal filters F1 and F2.

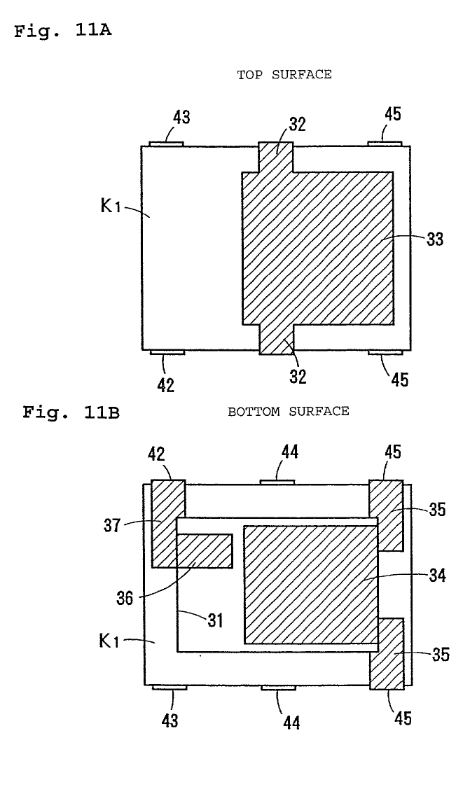

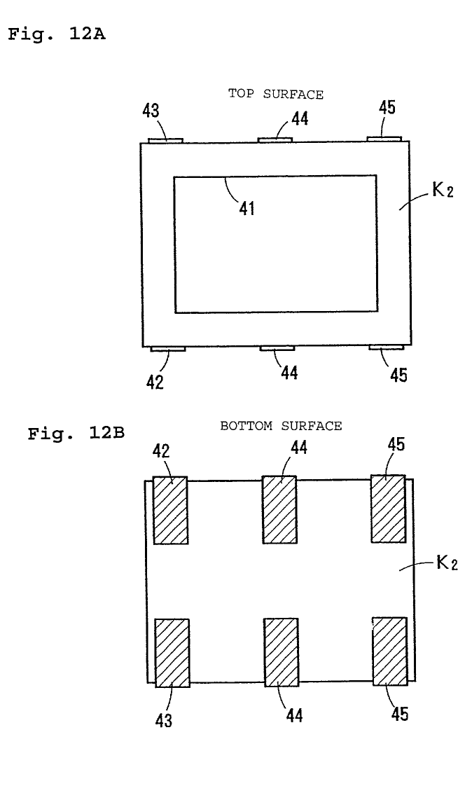

The first casing substrate K1 shown in FIG. 11A, which is bonded to the outside of the first three-terminal filter F1, includes an insulating substrate that is preferably made of a material which is not piezoelectric, such as a ceramic or a heat-resistant resin, and has a depression 31 therein for defining a vibration space, as shown in FIG. 11B. On the top surface of the casing substrate K1, a capacitor electrode 33, which is connected to two terminal electrodes 32 for grounding, is provided. On the bottom surface (the surface of the depression 31) of the casing substrate K1, a capacitor electrode 34 which faces the capacitor electrode 33, is provided. The capacitor electrode 34 is connected to two terminal electrodes 35 for relaying, which are provided on the two corners of the casing substrate K1. On the bottom surface of the casing substrate K1, a capacitor electrode 36 is disposed near the capacitor electrode 34. The capacitor electrode 36 is connected to a terminal electrode 37 for inputting a signal, which is disposed on the other corner of the casing substrate K1.

As shown in FIG. 7, a relay capacitance Cr is provided between the capacitor electrodes 33 and 34, which face each other, and an additional capacitance Ca is provided between the capacitor electrodes 34 and 36, which are located close to each other on the bottom surface of the first casing substrate K1. Preferably, the casing substrate is preferably made of a material having a dielectric constant that is the same as or close to those of the three-terminal filters F1 and F2.

The second casing substrate K2 also includes an insulating substrate which is not piezoelectric, as in the case of the first casing substrate K1. The second casing substrate K2 has a depression 41 therein for defining a vibration space, as shown in FIG. 12A. An external electrode 42 for inputting a signal is disposed at one end of one longitudinal side of the casing substrate K2. An external electrode 43 for outputting a signal is disposed at one end of the other longitudinal side of the casing substrate K2 so as to face the external electrode 42. The external electrodes 42 and 43 extend from the longitudinal sides to the bottom surface of the second casing substrate K2. At the approximate center of the longitudinal sides of the casing substrate K2, a pair of external electrodes 44 for grounding is arranged so as to extend from the sides to the bottom surface thereof. At the other ends of the longitudinal sides of the casing substrate K2, a pair of external electrodes 45 for relaying is arranged so as to extend from the longitudinal sides to the bottom surface thereof.

The external electrodes 42 to 45 are consecutively arranged on the longitudinal sides of the piezoelectric filter so that they define belts which extend along the thickness direction of the piezoelectric filter. Accordingly, the terminal electrode 12a exposed at the end surface of the three-terminal filter F1 and the terminal electrode 37 of the first casing substrate K1 are connected via the external electrode 42 for inputting the signal. The terminal electrode 13a of the three-terminal filter F1, the terminal electrode 23a of the three-terminal filter F2, and the terminal electrode 35 of the casing substrate K1 are connected via the external electrode 45 for relaying. The terminal electrode 14a of the three-terminal filter F1, the terminal electrode 24a of the three-terminal filter F2, and the terminal electrode 32 of the casing substrate K1 are connected via the external electrode 44 for grounding. The terminal electrode 22a that is exposed at the end surface of the three-terminal filter F2 is connected to the external electrode 43 for outputting the signal.

The piezoelectric filter includes the three-terminal filter F1 and the three-terminal filter F2 which are connected in a cascade arrangement via the relay capacitance Cr, and the additional capacitance Ca (=Ci) which is connected between an input part and an output part of one of the three-terminal filters F1 or F2 as shown in FIG. 3. In this preferred embodiment, the additional capacitance Ca is connected between the input part and the output part of the three-terminal filter F1.

In the first preferred embodiment, the additional capacitance Ca (=Ci) is connected between the input part and the output part of the first three-terminal filter F1. However, in a second preferred embodiment, the additional capacitance Ca (=Co) may be connected between the input part and the output part of the second three-terminal filter F2. Further, the casing substrates k1 and K2 have the depressions 31 and 41 in the first preferred embodiment. However, in the present preferred embodiment, the casing substrates K1 and K2 may be bonded by using a frame-shaped adhesive layer S, wherein the casing substrates K1 and K2 may not have the depressions 31 and 41.

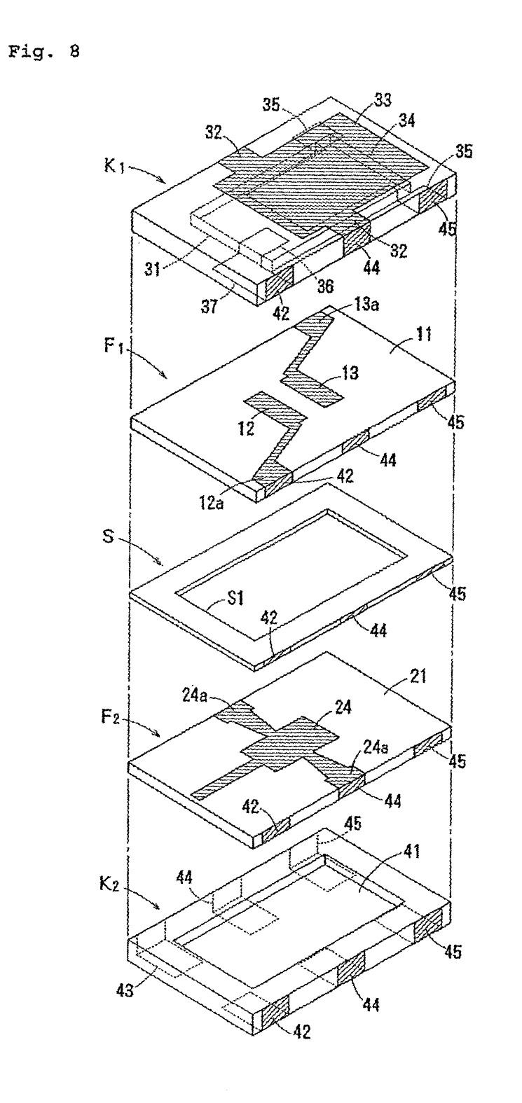

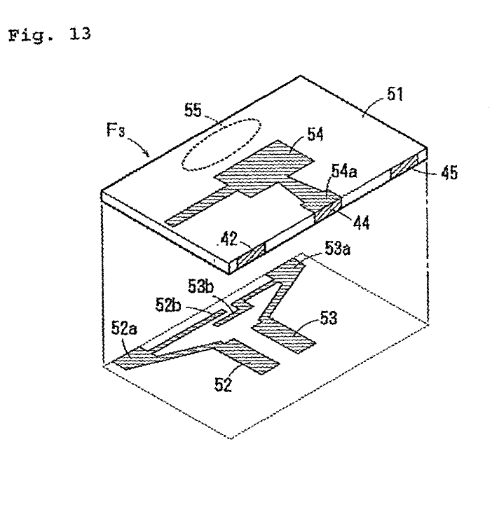

FIG. 13 shows a three-terminal filter F3 according to a third preferred embodiment which can be used for the piezoelectric filter of the present invention. This three-terminal filter F3 may be used, e.g., as a replacement for the three-terminal filter F2 shown in FIG. 8.

The three-terminal filter F3 includes a piezoelectric substrate 51 preferably made of a piezoelectric ceramic or a single piezoelectric crystal, and a split electrode 52 and a split electrode 53 which are arranged with a predetermined distance therebetween on the bottom surface of the piezoelectric substrate 51. The three-terminal filter F3 further includes a common electrode 54, which is disposed on the top surface of the piezoelectric substrate 51 and which faces the split electrodes 52 and 53. These split electrodes 52 and 53 and the common electrode 54 define a dual-mode filter that traps energy by using a thickness expander vibration. This drawing further shows the split electrodes 52 and 53 disposed on the bottom surface of the piezoelectric substrate 51 as a projection chart. The split electrode 52 is connected to a terminal electrode 52a for outputting a signal which is disposed on one of the corners of the piezoelectric substrate 51, and the split electrode 53 is connected to a terminal electrode 53a for relaying, which is disposed on the other corner thereof. The common electrode 54 is connected to a terminal electrode 54a for grounding disposed at the center of one longitudinal side of the piezoelectric substrate 51.

At the center of the other longitudinal side of the piezoelectric substrate 51, a non-polarizing part 55 is provided and is shown by the broken line in FIG. 13. In the vicinity of the non-polarizing part 55, capacitor electrodes 52b and 53b extending from the terminal electrode 52a and the terminal electrode 53a are disposed. The additional capacitance Ca is provided between these capacitor electrodes 52b and 53b.

In this preferred embodiment, the additional capacitance Ca is provided in the three-terminal filter F3. Therefore, the casing substrate K1 does not require the capacitor electrode 36 and the terminal electrode 37.

In the above-described preferred embodiments, the three-terminal filters preferably use the thickness expansion vibration mode. However, a different type of three-terminal filter using other vibration modes such as a shear vibration mode can be used.

The piezoelectric filter of the present invention is not limited to a chip-type piezoelectric filter including the filters and the casing substrates that are laminated on one another. For example, the piezoelectric filter may include two filters disposed on a casing substrate and a cap sealed thereon for sealing the filters.

While the present invention has been described with reference to what are at present considered to be preferred embodiments, it is to be understood that various changes and modifications may be made thereto without departing from the invention in its broader aspects and therefore, it is intended that the appended claims cover all such changes and modifications that fall within the true spirit and scope of the invention.

What is claimed is:

1. A piezoelectric filter comprising:
a first three-terminal filter having a first input part and a first output part;
a second three-terminal filter which has a second input part connected to the first output part, and a second output part;
a ground part;
a relay capacitance connected to the first output part, the second input part, and the ground part; and
an additional capacitance connected between the first input part and the first output part, or between the second input part and the second output part.

2. A piezoelectric filter according to claim 1, further comprising:
an input terminal for inputting a signal; and
an output terminal for outputting a signal,
wherein the value of the additional capacitance is at most about 1.5 times the value of a capacitance between the input terminal and the output terminal.

3. A piezoelectric filter according to claim 1, wherein the first three-terminal filter further comprises a first piezoelectric substrate, a first split electrode on one main surface of the first piezoelectric substrate, and a first common electrode, which faces the first split electrode, on the other main surface of the first piezoelectric substrate.

4. A piezoelectric filter according to claim 3, wherein the second three-terminal filter further comprises a second piezoelectric substrate, a second split electrode on one main surface of the second piezoelectric substrate, and a second common electrode, which faces the second split electrode, on the other main surface of the second piezoelectric substrate.

5. A piezoelectric filter according to claim 4, wherein the first piezoelectric substrate and the second piezoelectric substrate are laminated on and bonded to each other.

6. A piezoelectric filter according to claim 4, wherein the additional capacitance is provided on either the first piezoelectric substrate or the second piezoelectric substrate and between terminal electrodes which are connected to the first split electrode or the second split electrode.

7. A piezoelectric filter according to claim 3, wherein a first casing substrate is bonded to the outside of the first piezoelectric substrate, and comprises a first input terminal electrode and a first relay terminal electrode, which are connected to the first split electrode, and a first ground terminal electrode, which is connected to the first common electrode.

8. A piezoelectric filter according to claim 7, wherein the additional capacitance is provided between the first input terminal electrode and the first relay terminal electrode.

9. A piezoelectric filter according to claim 2, wherein the first three-terminal filter further comprises a first piezoelectric substrate, a first split electrode on one main surface of the first piezoelectric substrate, and a first common electrode, which faces the first split electrode, on the other main surface of the first piezoelectric substrate.

10. A piezoelectric filter according to claim 9, wherein the second three-terminal filter further comprises a second piezoelectric substrate, a second split electrode on one main surface of the second piezoelectric substrate, and a second common electrode, which faces the second split electrode, on the other main surface of the second piezoelectric substrate.

11. A piezoelectric filter according to claim 10, wherein the first piezoelectric substrate and the second piezoelectric substrate are laminated on and bonded to each other.

12. A piezoelectric filter according to claim 10, wherein the additional capacitance is provided on either the first piezoelectric substrate or the second piezoelectric substrate and between terminal electrodes which are connected to the first split electrode or the second split electrode.

13. A piezoelectric filter according to claim 9, wherein a first casing substrate is bonded to the outside of the first piezoelectric substrate, and comprises a first input terminal electrode and a first relay terminal electrode, which are connected to the first split electrode, and a first ground terminal electrode, which is connected to the first common electrode.

14. A piezoelectric filter according to claim 13, wherein the additional capacitance is provided between the first input terminal electrode and the first relay terminal electrode.

15. A piezoelectric filter according to claim 10, wherein a second casing substrate is bonded to the outside of the second piezoelectric substrate, and comprises a first output terminal electrode and a second relay terminal electrode, which are connected to the second split electrode, and a second ground terminal electrode, which is connected to the second common electrode.

16. A piezoelectric filter according to claim 15, wherein the additional capacitance is provided between the first output terminal electrode and the second relay terminal electrode.

17. A piezoelectric filter according to claim 15, wherein the relay terminal electrode and the ground terminal electrode are provided on the top surface and the bottom surface, respectively, of the second casing substrate so as to face each other, and the relay capacitance is provided between the relay terminal electrode and the ground terminal electrode.
